(19) United States
(12) Patent Application Publication
(10) Pub. No.: US 2024/0220677 A1
(43) Pub. Date: Jul. 4, 2024

(54) HYBRID DIGITAL TWIN SIMULATION

(71) Applicant: International Business Machines Corporation, Armonk, NY (US)

(72) Inventor: Sarbajit K. Rakshit, Kolkata (IN)

(21) Appl. No.: 18/147,026

(22) Filed: Dec. 28, 2022

(51) Int. Cl. G06F 30/20

(52) U.S. Cl. CPC G06F 30/20

(57) ABSTRACT

A processor may receive an entity data having one or more data components associated with an entity. The processor may analyze the entity data. The processor may identify, responsive to analyzing the entity data, one or more restricted data components and one or more unrestricted data components from the one or more data components. The processor may generate at least one federated digital twin model of the entity using the one or more restricted data components. The processor may generate a non-federated digital twin of the entity using the one or more unrestricted data components. The processor may aggregate the at least one federated digital twin and the non-federated digital twin to form a hybrid digital twin.

### BACKGROUND

The present disclosure relates generally to the field of artificial intelligence (AI), and more particularly to the field of digital twins.

Digital twin technology and traditional simulation both utilize virtual model-based simulations. A digital twin may replicate what is occurring with a specific object in the real world while the simulation capabilities of traditional computer-aided design and engineering often offer less versatile results. More particularly, a digital twin is a virtual model that is created to accurately reflect a physical object. Often, the physical object is fitted with sensors that generate or produce data corresponding to various aspects of the physical object's performance. The collected data may then be applied to the digital twin of the object. This allows the digital twin to generate more accurate simulations to study current performance of the object.

### SUMMARY

Embodiments of the present disclosure include a method, computer program product, and system for managing an one or more personal devices in a smart environment.

A processor may receive an entity data having one or more data components associated with an entity. The processor may analyze the entity data. The processor may identify, responsive to analyzing the entity data, one or more restricted data components and one or more unrestricted data components from the one or more data components. The processor may generate at least one federated digital twin model of the entity using the one or more restricted data components. The processor may generate a non-federated digital twin of the entity using the one or more unrestricted data components. The processor may aggregate the at least one federated digital twin and the non-federated digital twin to form a hybrid digital twin.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a block diagram of an embodiment of an hybrid digital twin system, in accordance with the present disclosure.

FIG. 2 illustrates a flowchart of a method for hybrid digital twin system, in accordance with embodiments of the present disclosure.

FIG. 3 depicts a block diagram illustrating an embodiment of a computer system and the components thereof, upon which embodiments described herein may be implemented in accordance with the present disclosure.

FIG. 4 depicts a block diagram illustrating an extension of the computing system environment of FIG. 3, wherein the computer systems are configured to operate in a network environment (including a cloud environment), and perform methods described herein in accordance with the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the disclosure.

### DETAILED DESCRIPTION

Aspects of the present disclosure relate generally to the field of artificial intelligence (AI), and more particularly to digital twin simulation. While the present disclosure is not necessarily limited to such applications, various aspects of the disclosure may be appreciated through a discussion of several examples using this context.

Digital twin simulation may provide a virtual environment where ideas can be tested with few limitations. A digital twin may be used to replicate what is occurring with a physical or non-physical object/asset. The physical object is often fitted with sensors (e.g., Internet of Things (IoT)) to produce or generate data associated with various aspects of the object's performance. The use of IoT sensors or devices allow for the collection of high-level information. This data may then be relayed to a processing system and applied to the digital twin. The fast transfer of data between the object and the digital twin enables a user to see how the object operates in real-time (e.g., mirroring the actual object, process, or system). The resulting digital twin may then be used to run different simulations that may be applied back to the physical object.

The more data collected regarding the actual object/asset (e.g., physical or non-physical object) and the corresponding digital twin, the more accurate and useful a digital twin usually becomes. In some situations, relevant data may be used to further configure a digital twin from other same or similar sources. For example, a digital twin of a wind turbine may reflect a single turbine, but the information/data utilized by the digital twin simulation system may utilize data associated with other same or similar wind turbines in order to more accurately reflect how the particular wind turbine of interest may be impacted under different conditions (e.g., how a wind turbine may be impacted by hurricane force wind) that the particular wind turbine has never experience (e.g., no related data available).

This use of other relevant data allows for more the generation of more accurate simulations and predictions for a particular object. Unfortunately, in some situations, this relevant data (e.g., user usage related information associated with driving a car) may be restricted for one or more reasons (e.g., privacy settings, confidential, user preferences, etc.). As such, there is a desire for a solution, in the form of a method, system, and computer program product, for generating an accurate and precise digital twin while also maintaining the various protections associated with relevant data. Such embodiments may further minimize the cost associated with using digital twin simulation and generating various digital twins.

Embodiments contemplated herein may receive an entity data (e.g., having one or more data components) from an entity (e.g., object or asset). In these embodiments, one or more restricted data components and one or more unrestricted data components may be identified by analyzing the one or more data components from the entity data. A federated digital twin of the entity may be generated using the one or more restricted data components while a non-federated digital twin of the entity may be generated using the one or more unrestricted data components. The federated digital twin and the non-federated digital twin may then be aggregated to form a hybrid digital twin that ensures the restricted data components (e.g., relevant information/data with constraints) are properly handled.

While embodiments contemplated herein may often refer to generating digital twins associated with product design, such embodiments should not be construed as limiting, as any application may be similarly substituted where digital twin simulation may utilize information/data that may be constrained in some way.

Before turning to the FIGS. it is noted that the benefits/novelties and intricacies of the proposed solution are that:

The hybrid digital twin system may be configured to identify appropriate hybrid model of digital twin simulation. This may be done while finalizing digital twin model of a product to be manufactured. This may allow a customer's privacy to be maintained and considered while finalizing the digital twin model of the product.

The hybrid digital twin system may be configured to identify if a set of user's usage patterns are to be considered during digital twin simulation. This may be performed while simulating any asset or service using the digital twin simulation.

The hybrid digital twin system may be configured to identify what types of data/information may be used for digital twin simulation. In some embodiments, the hybrid digital twin system may be configured to classify the data/information based on level of privacy. In these embodiments, the hybrid digital twin system may be configured to deciding the hybrid mode of digital twin simulation. For example, various combination ratio of federated and normal digital twin model.

The hybrid digital twin system may be configured to identify appropriate mode of aggregation of digital twin simulation for different classified data/information that may be used for digital twin simulation. In embodiments the aggregation of the digital twin simulation may be averaging, adding, or combining of the individual digital twin simulation model.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

It will be readily understood that the instant components, as generally described and illustrated in the figures herein, may be arranged and designed in a wide variety of different configurations. Accordingly, the following detailed description of the embodiments of at least one of a method, apparatus, non-transitory computer readable medium and system, as represented in the attached figures, is not intended to limit the scope of the application as claimed but is merely representative of selected embodiments.

The instant features, structures, or characteristics as described throughout this specification may be combined or removed in any suitable manner in one or more embodiments. For example, the usage of the phrases “example embodiments,” “some embodiments,” or other similar language, throughout this specification refers to the fact that a particular feature, structure, or characteristic described in connection with the embodiment may be included in at least one embodiment. Accordingly, appearances of the phrases “example embodiments,” “in some embodiments,” “in other embodiments,” or other similar language, throughout this specification do not necessarily all refer to the same group of embodiments, and the described features, structures, or characteristics may be combined or removed in any suitable manner in one or more embodiments. Further, in the FIGS., any connection between elements can permit one-way and/or two-way communication even if the depicted connection is a one-way or two-way arrow.

Also, any device depicted in the drawings can be a different device. For example, if a mobile device is shown sending information, a wired device could also be used to send the information. The term “module” may refer to a hardware module, software module, or a module may be a combination of hardware and software resources. Embodiments of hardware-based modules may include self-contained components such as chipsets, specialized circuitry, one or more memory devices and/or persistent storage. A software-based module may be part of a program, program code or linked to program code containing specifically programmed instructions loaded into a memory device or persistent storage device of one or more data processing systems operating as part of the computing environment (e.g., hybrid digital twin system 100).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application and to enable others of ordinary skill in the art to understand the disclosure for various embodiments with various modifications as are suited to the particular use contemplated.

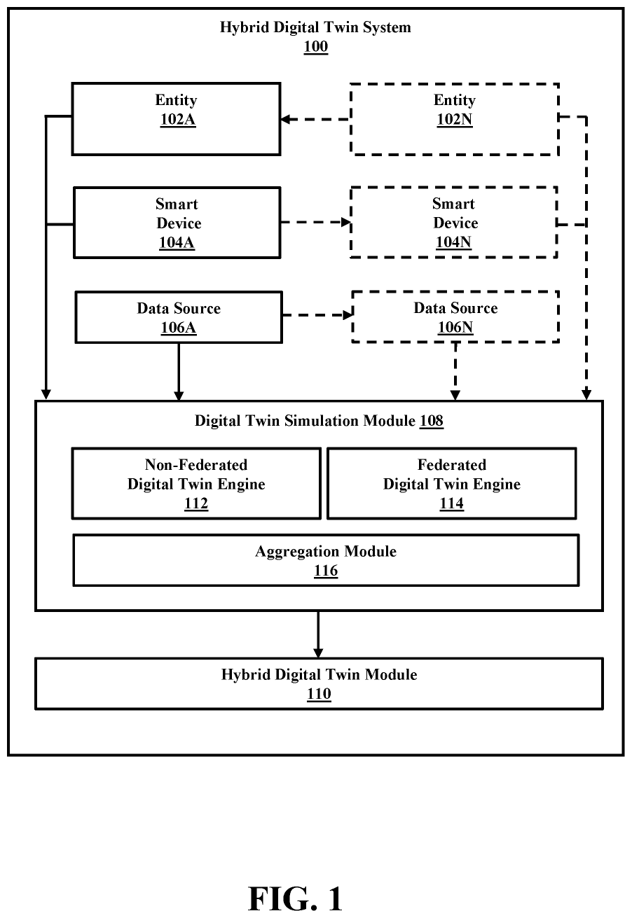

Turning now to the figures, FIG. 1 depicts hybrid digital twin system 100, in accordance with embodiments of the present disclosure. FIG. 1 provides an illustration of only one embodiment and does not imply any limitations with regard to the environments in which different embodiments may be implemented. Many modifications to the depicted environment may be made by those skilled in the art without departing from the scope of the invention as recited by the claims.

In embodiments, hybrid digital twin system 100 may be configured to include one or more entities 102A-102N, smart devices 104A-104N, data sources 106A-106N, digital twin simulation module 108 and hybrid digital twin 110. Hybrid digital twin system 100 may be enabled using AI and machine learning technology to generate a hybrid digital twin (e.g., via hybrid digital twin module 110) of an entity 102 (e.g., 102A-102N). An entity may refer to any object, asset, or service that may be simulated using digital twin simulation (e.g., wind turbines, automobiles, mobile phones, etc.).

In embodiments, hybrid digital twin system 100 may be configured to receive an entity data having one or more data components. The one or more data components associated with the collected/received entity data may include, but is not limited to: i) any information/data that may be utilized to generate a digital twin (e.g., types of data, volume of data, and data associated with IoT feeds); ii) information/data received/collected from one or more smart devices 104A-104N (e.g., real-time data from IoT sensors regarding the status of the entity); iii) relevant information from one or more same or similar entities (e.g., performance information from different automobile brands or automobiles with varied designs); iv) information/data generated from various analyses contemplated herein (e.g., information/data generated by AI and machine learning analysis via digital twin simulation module 108); v) external or other databases having information/data associated with the same or similar entities; and vi) information/data collected over time and stored in a historical repository (e.g., to be used digital twin simulation). The historical repository may include any entity data contemplated herein. In embodiments, hybrid digital twin system 100 may access the historical repository to generate one or more simulations using AI and machine learning capabilities (e.g., digital twin simulation module 108).

In some embodiments, hybrid digital twin system 100 may be configured to receive entity data (e.g., one or more data components) from one or more data sources 106A-106N. As contemplated herein, the more entity data available to digital twin simulation module 110, the more accurate and precise the generated digital twins of the entity will be. One or more data sources 106A-106N may include, but are not limited to, a user or group of users, a company, different departments within a company, IoT ecosystem, or data administrator (e.g., a user who monitors the use of various data components).

In embodiments, hybrid digital twin system 100 may be configured to analyze entity data (e.g., using AI and machine learning techniques and/or digital twin simulation module 108) from one or more data sources 106A-106N. In these embodiments, hybrid digital twin system 100 may identify, responsive to analyzing the entity data, one or more restricted data components and one or more unrestricted data components from the one or more data components received from data sources 106A-106B. An unrestricted data component may refer to a data component that may be utilized by hybrid digital twin system 100 without limit (e.g., as it relates to digital twin simulations), while a restricted data component may refer to data components that have one or more limiting measures or constraints that may limit how the entity data may be used or shared in hybrid digital twin system 100 (e.g., due to including sensitive information in the data components).

While in some embodiments, hybrid digital twin system 100 may determine whether a data component is an unrestricted data component or a restricted data component based a restriction policy (e.g., security policy or privacy policy), in other embodiments, hybrid digital twin system 100 may be configured to automatically classify the one or more components as an unrestricted data component or a restricted data component. A restriction policy may include rules or regulations indicating how the data components of entity data should be controlled. In one example embodiment, hybrid digital twin system 100 may be configured to receive automobile data (e.g., entity data) from Car Company A and Car Company B (e.g., data sources 106A-106N) who may be working together to identify possible automobile safety issues using digital twin simulations. In this example, Company A and Car Company B may each have data components that may be useful when producing the digital twin of the automobile based on historical automobile use by their customers. Due to terms and conditions agreed upon with Company A's and Car Company B's customers, some of these data components may not be shared outside of the particular company. As a result, all or less than all of data sources 106A-106N may have a restriction policy that provide limits regarding entity data 102A-102N may be shared outside of the particular data source.

In embodiments, hybrid digital twin system 100 may be configured to analyze the restriction policy associated with each of the one or more data sources 106A-106N. In these embodiments, hybrid digital twin system 100 may be configured to assign a restriction level (e.g., privacy level) to each of the one or more data components using the restriction policy associated with one or more data sources 106A-106N. In such embodiments, the higher the restriction level a data component has, the more limits the data component may have when utilized by digital twin system 100.

In embodiments, hybrid digital twin system 100 may be configured to analyze the restriction level of each of the one or more data components. In these embodiments, hybrid digital twin system 100 may then determine whether the restriction level of a particular data component of the one or more data components activates a restriction threshold (e.g., determined by the data source and/or restriction policy).

In embodiments where the restriction level of the particular data component is determined to not to activate a restriction threshold, hybrid digital twin system 100 may be configured to identify the particular data component as an unrestricted data component. Hybrid digital twin simulation 100 may then be compile the unrestricted data components to be used for digital twin simulation.

In embodiments where the restriction level of the particular data component is determined to activate a restriction threshold, hybrid digital twin system 100 may be configured to identify the particular data component as a restricted data component (e.g., of the one or more restricted data components). In these embodiments, hybrid digital twin simulation system 100 may be configured to federalize the restricted data components from a portion of the one or more data sources. In other words, hybrid digital twin system 100 gathers the restricted data components and ensures that only those data sources provided permission (e.g., via restriction policy and/or data source providing the entity data) may have access to the restricted data component (e.g., entity data). In one example embodiment, Car Company A may have restricted data components and unrestricted data components while Car Company B only has unrestricted data components. In this example embodiment, the restricted data components associated with Car Company A may be federalized and Car Company B's access to that entity data averted. Alternatively, the entity data from Car Company A and Car Company B that is determined to be unrestricted data components may be compiled for use by digital twin simulation module 108.

In embodiments, hybrid digital twin system 100 may be configured to generate a non-federated digital twin of the entity using non-federated digital twin engine 112 of digital twin simulation module 108. Non-federated digital twin engine 112 may generate one or more digital twins of the entity using only entity data determined to be unrestricted data components. In embodiments, hybrid digital twin system 100 may be configured to generate at least one federated digital twin of the entity using federated digital twin engine 114 of digital twin simulation module 108. Federated digital twin engine 114 may generate one or more digital twins of the entity using the one or more restricted data components.

In embodiments, once hybrid digital twin system 100 has generated a non-federated digital twin and at least one federated digital twin of the entity, digital twin simulation module 108 may use aggregation module 114 to aggregate the at least one federated digital twin and the non-federated digital twin. In embodiments, aggregation may refer to various methods of mixing of federated digital twins and non-federated digital twins. For example, hybrid digital twin system 100 may average, add, or a combination of adding or averaging the generated digital twin simulations. By aggregating the federated digital twin and the non-federated digital twin, a hybrid digital twin (e.g., hybrid digital twin 110) is formed while also ensuring the privacy or secrecy of the entity data (e.g., reasons for restricting access to particular entity data) provided by a particular data sources is maintained.

In some embodiments, hybrid digital twin system 100 may be configured to issue the hybrid digital twin 110 and associated results to one or more of the data sources who provided entity data for digital twin simulation module 108. In some embodiments, hybrid digital twin 110 may be included in a digital twin report. This digital twin report may include one or more manufacturing recommendations associated with the entity. In embodiments where digital twin simulation module 108 may be finalizing a digital twin of a particular entity to be manufactured, hybrid digital twin system 100 may be configured to ensure a customer's privacy.

In embodiments, while performing digital twin simulation of an entity, hybrid digital twin system 100 may be configured to identify a user's (e.g., data sources) usage patterns. Hybrid digital twin system 100 may use these usage patterns to determine a user's restriction level for their provided data components that may be considered during digital twin simulation. Based on this, hybrid digital twin system 100 may select to generate either a federated digital twin simulation or a non-federated digital twin simulation.

In some embodiments, hybrid digital twin system 100 may be configured to identify an appropriate mode of aggregation of digital twin simulation. This may be based on how the one or more data components associated with the entity are classified or assigned (e.g., restricted or unrestricted data components).

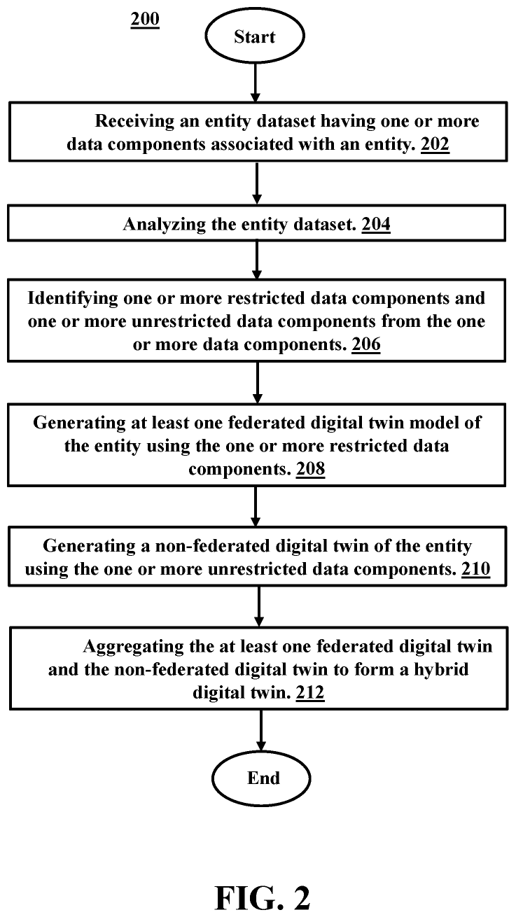

Referring now to FIG. 2, a flowchart illustrating an example method 200 for hybrid digital twin simulation, in accordance with embodiments of the present disclosure. FIG. 2 provides an illustration of only one implementation and does not imply any limitations with regard to the environments in which different embodiments may be implemented. Many modifications to the depicted environment may be made by those skilled in the art without departing from the scope of the invention as recited by the claims.

In some embodiments, the method 200 begins at operation 202. At operation 202 a processor may receive an entity data having one or more data components associated with an entity. The method 200 may proceed to operation 204.

At operation 204, a processor may analyze the entity data. The method 200 proceeds to operation 206.

At operation 206, a processor may identify, responsive to analyzing the entity data, one or more restricted data components and one or more unrestricted data components from the one or more data components. The method 200 proceeds to operation 208.

At operation 208, a processor may generate at least one federated digital twin of the entity using the one or more restricted data components. The method 200 proceeds to operation 210.

At operation 210, a processor may generate a non-federated digital twin of the entity using the one or more unrestricted data components. The method 200 proceeds to operation 212.

At operation 212, a processor may aggregate at least one federated digital twin and the non-federated digital twin to form a hybrid digital twin. In some embodiments, as depicted in FIG. 2, after operation 212, the method 200 may end.

In some embodiments, the processor may receive one or more restricted data components and the one or more unrestricted data components from one or more users.

In some embodiments, the processor may analyze a restriction policy associated with each of the one or more users. In these embodiments, the processor may assign a restriction level to each of the one or more data components, based at least in part on the restriction policy associated with each of the one or more users.

In some embodiments, the processor may analyze the restriction level of each of the one or more data components. In these embodiments, the processor may determine if the restriction level of a particular data component of the one or more data components activates a restriction threshold.

In some embodiments, the processor may identify, responsive to determining the restriction level of the particular data component of the one or more data component activates a restriction threshold, the particular data component as a restricted data component of the one or more restricted data components. In these embodiments, the processor may federalize the restricted data components of the one or more restricted data components from a portion of the one or more users.

In some embodiments, the processor may identify, responsive to determining the restriction level of the particular data component of the one or more data component does not activate a restriction threshold, the particular data component as an unrestricted data component of the one or more unrestricted data components. In these embodiments, the processor may compile the unrestricted data components of the one or more unrestricted data components.

In some embodiments, the processor may issue the hybrid digital twin to the one or more users. In these embodiments, the processor may generate a report having one or more manufacturing recommendations associated with the entity.

It is noted that various aspects of the present disclosure are described by narrative text, flowcharts, block diagrams of computer systems and/or block diagrams of the machine logic included in computer program product (CPP) embodiments. With respect to any flowcharts (depending upon the technology involved) the operations can be performed in a different order than what is shown in the flowchart. For example, two operations shown in successive flowchart blocks may be performed in reverse order, as a single integrated step, concurrently, or in a manner at least partially overlapping in time. A computer program product embodiment (“CPP embodiment”) is a term used in the present disclosure that may describe any set of one or more storage media (or “mediums”) collectively included in a set of one or more storage devices. The storage media may collectively include machine readable code corresponding to instructions and/or data for performing computer operations. A “storage device” may refer to any tangible hardware or device that can retain and store instructions for use by a computer processor. Without limitation, the computer readable storage medium may include an electronic storage medium, a magnetic storage medium, an optical storage medium, an electromagnetic storage medium, a semiconductor storage medium, a mechanical storage medium, and/or any combination thereof. Some known types of storage devices that include mediums referenced herein may include a diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination thereof. A computer-readable storage medium should not be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As understood by those skilled in the art, data is typically moved at some occasional points in time during normal operations of a storage device, such as during access, de-fragmentation or garbage collection, but this does not render the storage device as transitory because the data is not transitory while it is stored.

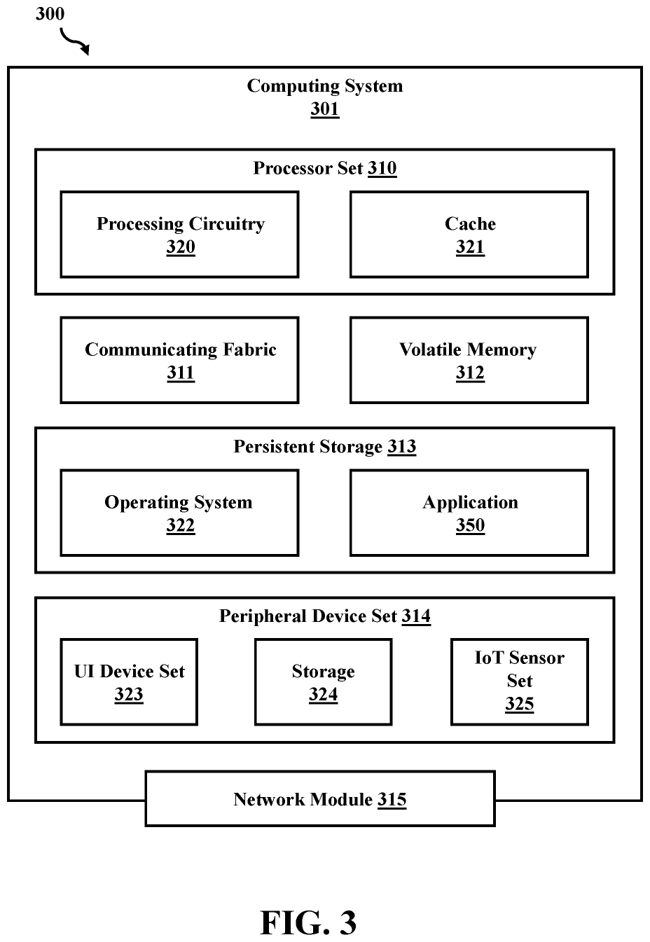

Referring now to FIG. 3, illustrated is a block diagram describing an embodiment of a computing system 301 within in a computing environment, which may be a simplified example of a computing device (i.e., a physical bare metal system and/or a virtual system) capable of performing the computing operations described herein. Computing system 301 may be representative of the one or more computing systems or devices implemented in accordance with the embodiments of the present disclosure and further described below in detail. It should be appreciated that FIG. 3 provides only an illustration of one implementation of a computing system 301 and does not imply any limitations regarding the environments in which different embodiments may be implemented. In general, the components illustrated in FIG. 3 may be representative of an electronic device, either physical or virtualized, capable of executing machine-readable program instructions.

Embodiments of computing system 301 may take the form of a desktop computer, laptop computer, tablet computer, smart phone, smart watch or other wearable computer, mainframe computer, server, quantum computer, a non-conventional computer system such as an autonomous vehicle or home appliance, or any other form of computer or mobile device now known or to be developed in the future that is capable of running a program 350, accessing a network 302 or querying a database, such as remote database 330. Performance of a computer-implemented method executed by a computing system 301 may be distributed among multiple computers and/or between multiple locations. Computing system 301 may be located as part of a cloud network, even though it is not shown within a cloud in FIGS. 3-2. Moreover, computing system 301 is not required to be in a cloud network except to any extent as may be affirmatively indicated.

Processor set 310 includes one, or more, computer processors of any type now known or to be developed in the future. Processing circuitry 320 may be distributed over multiple packages. For example, multiple, coordinated integrated circuit chips. Processing circuitry 320 may implement multiple processor threads and/or multiple processor cores. Cache 321 may refer to memory that is located on the processor chip package(s) and/or may be used for data or code that can be made available for rapid access by the threads or cores running on processor set 310. Cache 321 memories can be organized into multiple levels depending upon relative proximity to the processing circuitry 320. Alternatively, some, or all of cache 321 of processor set 310 may be located “off chip.” In some computing environments, processor set 310 may be designed for working with qubits and performing quantum computing.

Computer readable program instructions can be loaded onto computing system 301 to cause a series of operational steps to be performed by processor set 310 of computing system 301 and thereby implement a computer-implemented method. Execution of the instructions can instantiate the methods specified in flowcharts and/or narrative descriptions of computer-implemented methods included in this specification (collectively referred to as “the inventive methods”). The computer readable program instructions can be stored in various types of computer readable storage media, such as cache 321 and the other storage media discussed herein. The program instructions, and associated data, can be accessed by processor set 310 to control and direct performance of the inventive methods. In computing environments of FIGS. 3-2, at least some of the instructions for performing the inventive methods may be stored in persistent storage 313, volatile memory 312, and/or cache 321, as application(s) 350 comprising one or more running processes, services, programs and installed components thereof. For example, program instructions, processes, services and installed components thereof may include the components and/or sub-components of the system 100 as shown in FIG. 1.

Communication fabric 311 may refer to signal conduction paths that may allow the various components of computing system 301 to communicate with each other. For example, communications fabric 311 can provide for electronic communication among the processor set 310, volatile memory 312, persistent storage 313, peripheral device set 314 and/or network module 315. Communication fabric 311 can be made of switches and/or electrically conductive paths, such as the switches and electrically conductive paths that make up busses, bridges, physical input/output ports and the like. Other types of signal communication paths may be used, such as fiber optic communication paths and/or wireless communication paths.

Volatile memory 312 may refer to any type of volatile memory now known or to be developed in the future, and may be characterized by random access, but this is not required unless affirmatively indicated. Examples include dynamic type random access memory (RAM) or static type RAM. In computing system 301, the volatile memory 312 is located in a single package and can be internal to computing system 301, but, alternatively or additionally, the volatile memory 312 may be distributed over multiple packages and/or located externally with respect to computing system 301. Application 350, along with any program(s), processes, services, and installed components thereof, described herein, may be stored in volatile memory 312 and/or persistent storage 313 for execution and/or access by one or more of the respective processor sets 310 of the computing system 301.

Persistent storage 313 can be any form of non-volatile storage for computers that may be currently known or developed in the future. The non-volatility of this storage means that the stored data may be maintained regardless of whether power is being supplied to computing system 301 and/or directly to persistent storage 313. Persistent storage 313 may be a read only memory (ROM), however, at least a portion of the persistent storage 313 may allow writing of data, deletion of data and/or re-writing of data. Some forms of persistent storage 313 may include magnetic disks, solid-state storage devices, hard drives, flash-based memory, erasable read-only memories (EPROM) and semi-conductor storage devices. Operating system 322 may take several forms, such as various known proprietary operating systems or open-source Portable Operating System Interface type operating systems that employ a kernel.

Peripheral device set 314 includes one or more peripheral devices connected to computing system 301. For example, via an input/output (I/O interface). Data communication connections between the peripheral devices and the other components of computing system 301 may be implemented using various methods. For example, through connections using Bluetooth, Near-Field Communication (NFC), wired connections or cables (such as universal serial bus (USB) type cables), insertion type connections (for example, secure digital (SD) card), connections made though local area communication networks and/or wide area networks such as the internet. In various embodiments, UI device set 323 may include components such as a display screen, speaker, microphone, wearable devices (such as goggles, headsets and smart watches), keyboard, mouse, printer, touchpad, game controllers, and haptic feedback devices. Storage 324 can include external storage, such as an external hard drive, or insertable storage, such as an SD card. Storage 324 may be persistent and/or volatile. In some embodiments, storage 324 may take the form of a quantum computing storage device for storing data in the form of qubits. In some embodiments, networks of computing systems 301 may utilize clustered computing and components acting as a single pool of seamless resources when accessed through a network by one or more computing systems 301. For example, a storage area network (SAN) that is shared by multiple, geographically distributed computer systems 301 or network-attached storage (NAS) applications. IoT sensor set 325 can be made up of sensors that can be used in Internet-of-Things applications. For example, a sensor may be a temperature sensor, motion sensor, infrared sensor or any other type of known sensor type.

Network module 315 may include a collection of computer software, hardware, and/or firmware that allows computing system 301 to communicate with other computer systems through a network 302, such as a LAN or WAN. Network module 315 may include hardware, such as modems or Wi-Fi signal transceivers, software for packetizing and/or de-packetizing data for communication network transmission, and/or web browser software for communicating data over the network. In some embodiments, network control functions and network forwarding functions of network module 315 are performed on the same physical hardware device. In other embodiments (for example, embodiments that utilize software-defined networking (SDN)), the control functions and the forwarding functions of network module 315 can be performed on physically separate devices, such that the control functions manage several different network hardware devices. Computer readable program instructions for performing the inventive methods can typically be downloaded to computing system 301 from an external computer or external storage device through a network adapter card or network interface included in network module 315.

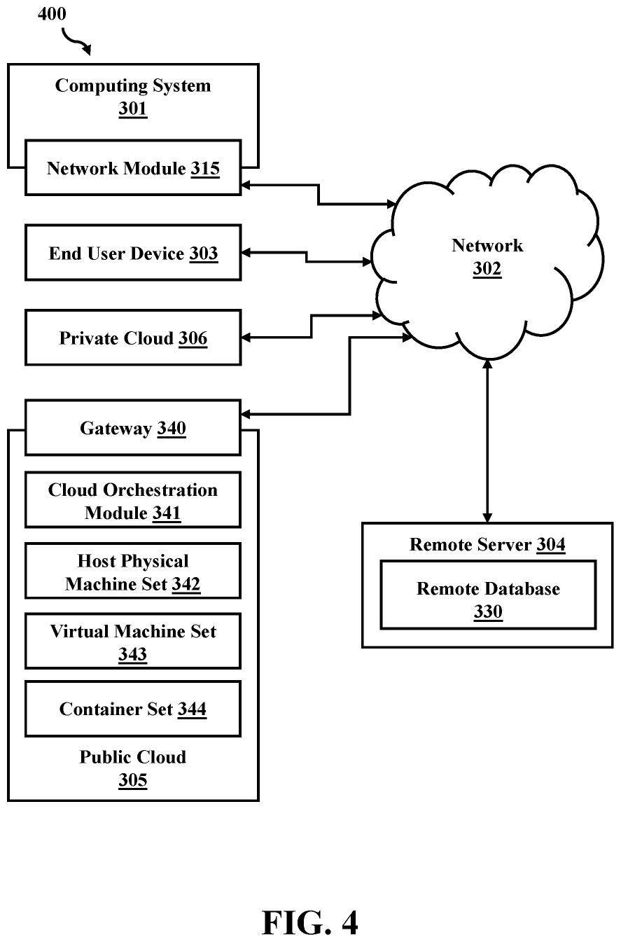

Continuing, FIG. 4 depicts a computing environment 400 which may be an extension of the computing environment 300 of FIG. 3, operating as part of a network. In addition to computing system 301, computing environment 400 can include a network 302 such as a wide area network (WAN) (or another type of computer network) connecting computing system 301 to an end user device (EUD) 303, remote server 304, public cloud 305, and/or private cloud 306. In this embodiment, computing system 301 includes processor set 310 (including processing circuitry 340 and cache 321), communication fabric 311, volatile memory 312, persistent storage 313 (including operating system 322 and program(s) 350, as identified above), peripheral device set 314 (including user interface (UI), device set 323, storage 324, Internet of Things (IOT) sensor set 325), and network module 315. Remote server 304 includes remote database 330. Public cloud 305 includes gateway 340, cloud orchestration module 341, host physical machine set 342, virtual machine set 343, and/or container set 344.

Network 302 may be comprised of wired or wireless connections. For example, connections may be comprised of computer hardware such as copper transmission cables, optical transmission fibers, wireless transmission, routers, firewalls, switches, gateway computers and/or edge servers. Network 302 may be described as any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. Other types of networks that can be used to interconnect the various computer systems 301, end user devices 303, remote servers 304, private cloud 306 and/or public cloud 305 may include Wireless Local Area Networks (WLANs), home area network (HAN), backbone networks (BBN), peer to peer networks (P2P), campus networks, enterprise networks, the Internet, single tenant or multi-tenant cloud computing networks, the Public Switched Telephone Network (PSTN), and any other network or network topology known by a person skilled in the art to interconnect computing systems 301.

End user device 303 can include any computer device that can be used and/or controlled by an end user (for example, a customer of an enterprise that operates computing system 301) and may take any of the forms discussed above in connection with computing system 301. EUD 303 may receive helpful and useful data from the operations of computing system 301. For example, in a hypothetical case where computing system 301 is designed to provide a recommendation to an end user, this recommendation may be communicated from network module 315 of computing system 301 through WAN 302 to EUD 303. In this example, EUD 303 can display, or otherwise present, the recommendation to an end user. In some embodiments, EUD 303 may be a client device, such as thin client, thick client, mobile computing device such as a smart phone, mainframe computer, desktop computer and so on.

Remote server 304 may be any computing systems that serves at least some data and/or functionality to computing system 301. Remote server 304 may be controlled and used by the same entity that operates computing system 301. Remote server 304 represents the machine(s) that collect and store helpful and useful data for use by other computers, such as computing system 301. For example, in a hypothetical case where computing system 301 is designed and programmed to provide a recommendation based on historical data, the historical data may be provided to computing system 301 from remote database 330 of remote server 304.

Public cloud 305 may be any computing systems available for use by multiple entities that provide on-demand availability of computer system resources and/or other computer capabilities including data storage (cloud storage) and computing power, without direct active management by the user. The direct and active management of the computing resources of public cloud 305 can be performed by the computer hardware and/or software of cloud orchestration module 341. The computing resources provided by public cloud 305 can be implemented by virtual computing environments that run on various computers making up the computers of host physical machine set 342, and/or the universe of physical computers in and/or available to public cloud 305. The virtual computing environments (VCEs) may take the form of virtual machines from virtual machine set 343 and/or containers from container set 344. It is understood that these VCEs may be stored as images and may be transferred among and between the various physical machine hosts, either as images or after instantiation of the VCE. Cloud orchestration module 341 manages the transfer and storage of images, deploys new instantiations of VCEs and manages active instantiations of VCE deployments. Gateway 340 is the collection of computer software, hardware, and firmware that allows public cloud 305 to communicate through network 302.

VCEs can be stored as “images.” A new active instance of the VCE can be instantiated from the image. Two types of VCEs may include virtual machines and containers. A container is a VCE that uses operating-system-level virtualization, in which the kernel allows the existence of multiple isolated user-space instances, called containers. These isolated user-space instances may behave as physical computers from the point of view of programs 350 running in them. An application 350 running on an operating system 322 can utilize all resources of that computer, such as connected devices, files and folders, network shares, CPU power, and quantifiable hardware capabilities. Applications 350 running inside a container of container set 344 may only use the contents of the container and devices assigned to the container, a feature which may be referred to as containerization.

Private cloud 306 may be similar to public cloud 305, except that the computing resources may only be available for use by a single enterprise. While private cloud 306 is depicted as being in communication with network 302 (such as the Internet), in other embodiments a private cloud 306 may be disconnected from the internet entirely and only accessible through a local/private network. A hybrid cloud may refer to a composition of multiple clouds of different types (for example, private, community or public cloud types), and the plurality of clouds may be implemented or operated by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 305 and private cloud 306 may be both part of a larger hybrid cloud environment.

What is claimed is:

1. A computer implemented method, the method comprising:
receiving, by a processor, an entity data having one or more data components associated with an entity;
analyzing the entity data;
identifying, responsive to analyzing the entity data, one or more restricted data components and one or more unrestricted data components from the one or more data components;
generating at least one federated digital twin of the entity using the one or more restricted data components;
generating a non-federated digital twin of the entity using the one or more unrestricted data components; and
aggregating the at least one federated digital twin and the non-federated digital twin to form a hybrid digital twin.

2. The computer implemented method of claim 1, wherein one or more data sources collect the one or more restricted data components and the one or more unrestricted data components.

3. The computer implemented method of claim 2, further including:
analyzing a restriction policy associated with each of the one or more data sources; and
assigning a restriction level to each of the one or more data components, based at least in part on the restriction policy associated with each of the one or more data sources.

4. The computer implemented method of claim 3, further including:
analyzing the restriction level of each of the one or more data components; and
determining whether the restriction level of a particular data component of the one or more data components activates a restriction threshold.

5. The computer implemented method of claim 4, further including:
identifying, responsive to determining the restriction level of the particular data component of the one or more data component activates a restriction threshold, the particular data component as a restricted data component of the one or more restricted data components; and
federalizing the restricted data component of the one or more restricted data components from a portion of the one or more data sources.

6. The computer implemented method of claim 4, further including:
identifying, responsive to determining the restriction level of the particular data component of the one or more data component does not activate a restriction threshold, the particular data component as an unrestricted data component of the one or more unrestricted data components; and
compiling the unrestricted data components of the one or more unrestricted data components.

7. The method of claim 1, further comprising:
issuing the hybrid digital twin to the one or more data sources; and
generating a report having one or more manufacturing recommendations associated with the entity.

8. A system, the system comprising:
a memory; and
a processor in communication with the memory, the processor being configured to perform operations comprising:
receiving an entity data having one or more data components associated with an entity;
analyzing the entity data;
identifying, responsive to analyzing the entity data, one or more restricted data components and one or more unrestricted data components from the one or more data components;
generating at least one federated digital twin of the entity using the one or more restricted data components;
generating a non-federated digital twin of the entity using the one or more unrestricted data components; and
aggregating the at least one federated digital twin and the non-federated digital twin to form a hybrid digital twin.

9. The system of claim 8, wherein one or more data sources collect the one or more restricted data components and the one or more unrestricted data components.

10. The system of claim 9, further including:
analyzing a restriction policy associated with each of the one or more data sources; and
assigning a restriction level to each of the one or more data components, based at least in part on the restriction policy associated with each of the one or more data sources.

11. The system of claim 10, further including:
analyzing the restriction level of each of the one or more data components; and
determining whether the restriction level of a particular data component of the one or more data components activates a restriction threshold.

12. The system of claim 11, further including:
identifying, responsive to determining the restriction level of the particular data component of the one or more data component activates a restriction threshold, the particular data component as a restricted data component of the one or more restricted data components; and
federalizing the restricted data component of the one or more restricted data components from a portion of the one or more data sources.

13. The system of claim 11, further including:
identifying, responsive to determining the restriction level of the particular data component of the one or more data component does not activate a restriction threshold, the particular data component as an unrestricted data component of the one or more unrestricted data components; and
compiling the unrestricted data components of the one or more unrestricted data components.

14. The system of claim 8, further comprising:
issuing the hybrid digital twin to the one or more data sources; and
generating a report having one or more manufacturing recommendations associated with the entity.

15. A computer program product, the computer program product comprising a computer readable storage medium having program instructions embodied therewith, the program instructions executable by a processor to cause the processors to perform a function, the function comprising:
receiving an entity data having one or more data components associated with an entity;
analyzing the entity data;
identifying, responsive to analyzing the entity data, one or more restricted data components and one or more unrestricted data components from the one or more data components;
generating at least one federated digital twin of the entity using the one or more restricted data components;
generating a non-federated digital twin of the entity using the one or more unrestricted data components; and
aggregating the at least one federated digital twin and the non-federated digital twin to form a hybrid digital twin.

16. The computer implemented method of claim 15, wherein one or more data sources collect the one or more restricted data components and the one or more unrestricted data components.

17. The computer implemented method of claim 16, further including:
analyzing a restriction policy associated with each of the one or more data sources; and
assigning a restriction level to each of the one or more data components, based at least in part on the restriction policy associated with each of the one or more data sources.

18. The computer implemented method of claim 17, further including:
analyzing the restriction level of each of the one or more data components; and
determining whether the restriction level of a particular data component of the one or more data components activates a restriction threshold.

19. The computer implemented method of claim 18, further including:
identifying, responsive to determining the restriction level of the particular data component of the one or more data component activates a restriction threshold, the particular data component as a restricted data component of the one or more restricted data components; and
federalizing the restricted data component of the one or more restricted data components from a portion of the one or more data sources.

20. The computer implemented method of claim 18, further including:
identifying, responsive to determining the restriction level of the particular data component of the one or more data component does not activate a restriction threshold, the particular data component as an unrestricted data component of the one or more unrestricted data components; and
compiling the unrestricted data components of the one or more unrestricted data components.
